(19) United States
(12) Patent Application Publication
(10) Pub. No.: US 2024/0095425 A1
(43) Pub. Date: Mar. 21, 2024

(54) SYSTEMS AND METHODS FOR PREDICTING MICROHARDNESS PROPERTIES OF WELDS

(71) Applicants: GM GLOBAL TECHNOLOGY OPERATIONS LLC, Detroit, MI (US); Arizona Board of Regents on behalf of Arizona State University, Scottsdale, AZ (US)

(72) Inventors: Ying Lu, Novi, MI (US); Junjie Ma, Troy, MI (US); Hui-ping Wang, Troy, MI (US); Mitchell Poirier, Owosso, MI (US); Baixuan Yang, Canton, MI (US); Jay Oswald, Chandler, AZ (US)

(73) Assignees: GM GLOBAL TECHNOLOGY OPERATIONS LLC, Detroit, MI (US); Arizona Board of Regents on behalf of Arizona State University, Scottsdale, AZ (US)

(21) Appl. No.: 17/933,495

(22) Filed: Sep. 20, 2022

(51) Int. Cl. G06F 30/27; B23K 9/095

(52) U.S. Cl. CPC G06F 30/27; B23K 9/0953

(57) ABSTRACT

Systems and methods are provided for predicting microhardness properties of a weld that defines a weld joint between at least two workpieces. The system includes a processor programmed to: receive temperature data that includes temperature values each attributed to a corresponding one of a plurality of points of the weld at corresponding times during a welding process used to produce the weld, determine peak temperature values and cooling rate values for each of the points of the weld based on the temperature values, predict a three-dimensional (3D) distribution of microhardness values of the weld based on a machine learning method that evaluates the peak temperature values and the cooling rate values, and generate display data based on the 3D distribution of microhardness values.

### INTRODUCTION

The technical field generally relates to material testing and material property prediction, and more particularly relates to a system and method for predicting three-dimensional (3D) distributions of microhardness values of fusion and solid-state welds.

Computer-aided engineering (CAE) is the use of software (e.g., CAE tools) to aid in engineering analysis, such as simulating effects of different conditions on products and/or structures using simulated loads and constraints. CAE tools encompass simulation, validation, and optimization of products and manufacturing tools, including designs created within computer-aided design (CAD) software. Major categories of CAE tools include finite element analysis (FEA), computational fluid dynamics (CFD), and multi-disciplinary design optimization (MDO).

CAE tools are widely used in the automotive industry, enabling automakers to reduce product development costs and time while improving the safety, comfort, and durability of the vehicles they produce. The predictive capability of CAE tools has progressed to the point where much of the design verification is done using computer simulations (e.g., diagnosis) rather than physical prototype testing.

For products that include welds, such as various vehicles, microhardness distribution of the welds are crucial input data for CAE analysis. Micro-indentation hardness testing, also referred to as microhardness testing, is commonly used to measure hardness in local regions, such as within a fusion zone and a heat affected zone (HAZ) of the workpieces. The test involves producing an indentation on a surface of a specimen through the application of a load with an indenter. Subsequently, the indenter is removed from the surface and the size of the impression is measured using a microscope. The resulting hardness is evaluated as a mean stress applied underneath the indenter.

A conventional, two-dimensional microhardness distribution may be determined for a weld by measuring microhardness in multiple points on a cross-section of a weld, and plotting the measured microhardness to position. To obtain additional information, such as microhardness characteristics of a heat-affected zone (HAZ), a three-dimensional (3D) microhardness distribution may be produced. However, obtaining an accurate 3D microhardness distribution can be quite difficult and time-consuming, requiring a significant quantity of physical testing.

Accordingly, it is desirable to provide systems and methods capable of producing a 3D microhardness distribution of a weld in a time-saving and accurate manner. In addition, it is desirable to produce 3D microhardness distributions of weld with reduced reliance on physical testing techniques. Furthermore, other desirable features and characteristics of the present invention will become apparent from the subsequent detailed description and the appended claims, taken in conjunction with the accompanying drawings and the foregoing technical field and background.

### SUMMARY

A system is provided for predicting microhardness properties of a weld that defines a weld joint between at least two workpieces. In various embodiments, the system includes a processor programmed to: receive temperature data that includes temperature values each attributed to a corresponding one of a plurality of points of the weld at corresponding times during a welding process used to produce the weld, determine peak temperature values and cooling rate values for each of the points of the weld based on the temperature values, predict a three-dimensional (3D) distribution of microhardness values of the weld based on a machine learning method that evaluates the peak temperature values and the cooling rate values, and generate display data based on the 3D distribution of microhardness values.

In an embodiment, the processor is further programmed to: receive composition data that includes compositions of the at least two workpieces, receive material microhardness data that includes microhardness values of the base metals of the at least two workpieces, and predict the 3D distribution of microhardness values of the weld based on the machine learning method that evaluates the peak temperature values, the cooling rate values, the compositions of the at least two workpieces, and the microhardness values of the base metals.

In an embodiment, the processor is further programmed to: simulate the temperature values using a welding process simulation model, and generate the temperature data includes the simulated temperature values.

In an embodiment, the system includes a temperature sensor configured to: sense the temperature values during the welding process, and transmit the sensed temperature values to the processor as the temperature data. In some embodiments, the at least two workpieces are formed of a mild steel, and the processor determines the cooling rates in a temperature range of between about 800° C. and 500° C. In some embodiments, the at least two workpieces are formed of an advanced high strength steel, and the processor determines the cooling rates in a temperature range of between about 750° C. and 300° C.

In an embodiment, the processor is further programmed to: provide the 3D distribution of microhardness values to a computer-aided engineering (CAE) tool as input data, and perform an analysis with the CAE tool using the 3D distribution of microhardness values as input.

In an embodiment, the at least two workpieces are formed of an advanced high strength steel with certain volume fraction of martensite in the base metal thereof, the heat affected zone of the weld includes a tempered zone, at least some of the microhardness values of the 3D distribution are attributed to points within the tempered zone, and the processor is programmed to predict the 3D distribution of microhardness values without using tempering kinetics of martensite produced experimentally for the tempered zone.

In an embodiment, the processor is further programmed to: receive two-dimensional (2D) distribution data that includes a two-dimensional (2D) distribution of microhardness values each attributed to a corresponding one of the plurality of points of the weld, correlate, by the machine learning method, the 2D distribution of microhardness values with the peak temperature values and the cooling rate values of the weld to provide correlation results, and train a neural network with the correlation results to predict the 3D distribution of microhardness values of the weld.

In an embodiment, the processor is further programmed to: receive two-dimensional (2D) distribution data that includes a two-dimensional (2D) distribution of microhardness values each attributed to a corresponding one of the plurality of points of the weld after solidification of the weld, receive composition data that includes compositions of the at least two workpieces, receive material microhardness data that includes microhardness values of the base metals of the at least two workpieces, correlate, by the machine learning method, the 2D distribution of microhardness values with the peak temperature values, the cooling rate values, the compositions, and the microhardness values of the base metals of the at least two workpieces to provide correlation results, and train a neural network with the correlation results to predict the 3D distribution of microhardness values of the weld.

In an embodiment, the system includes a microhardness testing device configured to: measure the 2D distribution of microhardness values of the weld, and transmit the 2D distribution of microhardness values to the processor as the 2D distribution data.

A computer implemented method is provided for predicting microhardness properties of a weld that defines a weld joint between at least two workpieces. In various embodiments, the method includes, by a processor: receiving temperature data that includes temperature values each attributed to a corresponding one of a plurality of points of the weld at corresponding times during a welding process used to produce the weld, determining peak temperature values and cooling rate values for each of the points of the weld based on the temperature values, predicting a three-dimensional (3D) distribution of microhardness values of the weld based on a machine learning method that evaluates the peak temperature values and the cooling rate values, and generating display data based on the 3D distribution of microhardness values.

In an embodiment, the method includes, by the processor: receiving composition data that includes compositions of the at least two workpieces, receiving material microhardness data that includes microhardness values of the base metals of the at least two workpieces, and predicting the 3D distribution of microhardness values of the weld based on the machine learning method that evaluates the peak temperature values, the cooling rate values, the compositions of the at least two workpieces, and the microhardness values of the base metals.

In an embodiment, the method includes, by the processor: simulating the temperature values using a welding process simulation model, and generating the temperature data includes the simulated temperature values.

In an embodiment, the method includes sensing, with a temperature sensor, the temperature values during the welding process, and transmitting the sensed temperature values to the processor as the temperature data. In an embodiment, the at least two workpieces are formed of a mild steel, and the processor determines the cooling rates in a temperature range of between about 800° C. and 500° C. In an embodiment, the at least two workpieces are formed of an advanced high strength steel, and the processor determines the cooling rates in a temperature range of between about 750° C. and 300° C.

In an embodiment, the method includes, by the processor: providing the 3D distribution of microhardness values to a computer-aided engineering (CAE) tool as input data, and performing an analysis with the CAE tool using the 3D distribution of microhardness values as input.

In an embodiment, the weld includes a tempered zone which includes martensite in a base metal of the weld, at least some of the microhardness values of the 3D distribution are attributed to points within the tempered zone, and the method further includes, by the processor, predicting the 3D distribution of microhardness values without using tempering kinematics produced experimentally for the tempered zone.

In an embodiment, the method includes, by the processor: receiving two-dimensional (2D) distribution data that includes a two-dimensional (2D) distribution of microhardness values each attributed to a corresponding one of the plurality of points of the weld, correlating, by the machine learning method, the 2D distribution of microhardness values with the peak temperature values and the cooling rate values of the weld to provide correlation results, and training a neural network with the correlation results to predict the 3D distribution of microhardness values of the weld.

In an embodiment, the method includes, by the processor: receiving two-dimensional (2D) distribution data that includes a two-dimensional (2D) distribution of microhardness values each attributed to a corresponding one of the plurality of points of the weld, receiving composition data that includes compositions of the at least two workpieces, receiving material microhardness data that includes microhardness values of the base metals of the at least two workpieces, and correlating, by the machine learning method, the 2D distribution of microhardness values with the peak temperature values, the cooling rate values, the compositions, and the microhardness values to provide correlation results, and training a neural network with the correlation results to predict the 3D distribution of microhardness values of the weld.

In an embodiment, the method includes, by a microhardness testing device: measuring the 2D distribution of microhardness values of the weld, and transmitting the 2D distribution of microhardness values to the processor as the 2D distribution data.

### BRIEF DESCRIPTION OF THE DRAWINGS

The exemplary embodiments will hereinafter be described in conjunction with the following drawing figures, wherein like numerals denote like elements, and wherein:

FIG. 1 is prediction system configured to predict microhardness values of a weld in accordance with an embodiment;

FIG. 2 is a data flow diagram of the system of FIG. 1 in accordance with an embodiment;

FIG. 3 is a flowchart illustrating a training method in accordance with an embodiment;

FIG. 4 is a first neural network in accordance with an embodiment;

FIG. 5 is a second neural network in accordance with an embodiment;

FIG. 6 is a flowchart illustrating an execution method in accordance with an embodiment.

### DETAILED DESCRIPTION

The following detailed description is merely exemplary in nature and is not intended to limit the application and uses. Furthermore, there is no intention to be bound by any expressed or implied theory presented in the preceding technical field, background, brief summary or the following detailed description. As used herein, the term module and/or system refers to any hardware, software, firmware, electronic control component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments of the present disclosure may be practiced in conjunction with any number of systems, and that the systems described herein are merely exemplary embodiments of the present disclosure.

For the sake of brevity, conventional techniques related to signal processing, machine learning, data transmission, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

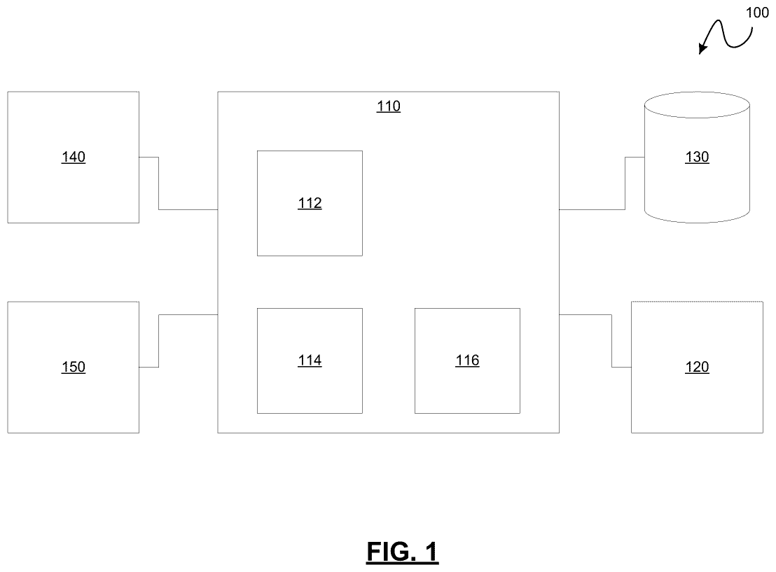

FIG. 1 illustrates a microhardness prediction system 100 configured for generating a prediction of a full-field, three-dimensional (3D) distribution of microhardness values (also referred to as a three-dimensional (3D) microhardness distribution) of a weld produced by a welding process that defines a weld joint between at least two workpieces according to an exemplary embodiment. Although the microhardness prediction system 100 is primarily discussed herein in relation to predicting of a 3D microhardness distribution for a weld, it should be understood that the microhardness prediction system 100 may be configured to generate a prediction of a 3D microhardness distribution for various objects formed by various processes wherein the objects undergo a thermal treatment or temperature change that may affect microhardness values of the objects.

In various embodiments, the microhardness prediction system 100 is configured to generate a prediction of a 3D microhardness distribution for a weld formed by a fusion welding process or a solid-state welding process. Fusion welding refers to welding processes that rely on melting to join workpieces. Due to high-temperature phase transitions inherent to these processes, a heat-affected zone and a fusion zone is usually created in the workpieces. Exemplary fusion welding processes include, but are not limited to, arc welding, energy beam welding (e.g., laser beam or electron beam), and chemical welding (e.g., gas/flame welding, solid reactant, etc.). Solid-state welding refers to welding processes that do not involve melting of the workpieces to be joined. Exemplary solid-state welding processes include, but are not limited to, ultrasonic welding, explosion welding, friction welding, magnetic pulse welding, co-extrusion welding, cold welding, diffusion bonding welding, exothermic welding, high frequency welding, hot pressure welding, induction welding processes, and roll bonding.

In various embodiments, the microhardness prediction system 100 is configured to generate a prediction of a 3D microhardness distribution for a weld formed of various similar or dissimilar materials. Nonlimiting examples of workpiece materials include various carbon steels, such as mild or low-carbon steel with a composition having about 0.05-0.30 wt. % carbon, medium-carbon steel with a composition having about 0.31-0.50 wt. % carbon, high-carbon steel with a composition having about 0.51 to 1.0 wt. % carbon, and ultra-high-carbon steel with a composition having about 1.1-2.0 wt. % carbon. Additional nonlimiting examples of workpiece materials include high-strength low-alloy (HSLA) steel, for example, with a composition having about 0.05-0.25 wt. % carbon as well as other alloying elements such as 2.0% manganese, and/or lower contents of copper, nickel, niobium, nitrogen, vanadium, chromium, molybdenum, titanium, calcium, rare-earth elements, or zirconium. In various embodiments, the workpieces may be formed of HSLA steels as defined by the Society of Automotive Engineers (SAE) standards such as SAE 945A, 950A, 950D, 945X, 950B, 950X, 945C, 955X, 950C, and 942X. Additional nonlimiting examples of workpiece materials include advanced high strength steel (AHSS) such as dual phase and transformation-induced plasticity steels. AHSSs include all martensitic and multiphase steels having a minimum specified tensile strength of at least 440 MPa. Typically, AHSSs rely on retained austenite in a bainite or martensite matrix and potentially some amount of ferrite and/or precipitates, all in specific proportions and distributions, to develop enhanced properties.

Referring again to FIG. 1, the microhardness prediction system 100 includes, but is not limited to, a prediction computer system 110, a user interface 120, a data storage device 130, a microhardness testing device 140, and a temperature sensor 150 (or temperature measuring device). The microhardness prediction system 100 is configured for using one or more machine learning methods, and includes a training process for construction of a microhardness prediction module and an execution process for predicting 3D microhardness distributions of weld using a trained microhardness prediction module.

The microhardness testing device 140 performs microhardness testing on weld. The microhardness testing device 140 includes an indenter (i.e., indenter probe) configured to contact a surface of a specimen under a predetermined load (e.g., 10 N or less) to form an indentation in the surface. The resulting indentation is analyzed to determine a microhardness value. In various embodiments, the size or the depth of the indentation is measured using an optical microscope. The resulting microhardness value may be evaluated as a mean stress applied underneath the indenter with the predetermined load. Nonlimiting testing devices include Vickers-type microhardness testing devices, Knoop-type microhardness testing devices, and instrumented indentation-type microhardness testing devices (e.g., using a three-sided pyramidal (Berkovich) indenter). The microhardness testing device 140 may include a computer system configured to generate a 2D microhardness map based on microhardness values corresponding to a plurality of points on a specimen that are obtained as described above. Alternatively, the 2D microhardness map may be generated by the prediction computer system 110 based on the 2D microhardness values received from the microhardness testing device 140.

The temperature sensor 150 senses temperatures of the workpieces, the weld, and/or areas of the workpieces adjacent to the weld (i.e., field) during a welding process. The temperature sensor 150 may include various types of devices and implement various techniques to obtain temperatures of the weld. As nonlimiting examples, temperatures of the weld may be measured at various times at various locations on the weld using an infrared temperature sensor or measuring device and/or a thermocouple sensor. Alternatively, in various embodiments, the prediction computer system 110 may receive simulated temperature values of the workpieces, the weld, and/or areas of the workpieces adjacent to the weld rather than sensing or measuring the temperature values. In these embodiments, the prediction computer system 110 may be coupled to a computer system configured to simulate temperature values of various points on, in, and/or adjacent to the weld during the welding process using a computer implemented welding process simulation model to obtain simulated temperature values. In various embodiments, the computer system may generate a temperature distribution including temperature values at the plurality of points of the weld based on the simulated temperature values. In various embodiments, the temperature values include temperatures within a temperature range between the peak temperature value and a threshold temperature obtained or simulated at a plurality of time points. As used herein the threshold temperature refers to a temperature at which the heated portions of the workpieces and/or weld reach a stable state in which there is no further phase or microstructural changes occurring as the workpieces continue to cool to room temperature.

The data storage device 130 stores data for use in the training and execution processes. As can be appreciated, the data storage device 130 may be part of the prediction computer system 110, separate from the prediction computer system 110, or part of the prediction computer system 110 and part of a separate system. The data storage device 130 can be any suitable type of storage apparatus, including various different types of direct access storage and/or other memory devices. In one exemplary embodiment, the data storage device 130 comprises a program product from which a computer readable memory device can receive a program that executes one or more embodiments of one or more processes of the present disclosure. In another exemplary embodiment, the program product may be directly stored in and/or otherwise accessed by the memory device and/or one or more other disks and/or other memory devices.

The prediction computer system 110 includes a processor 112, a computer readable storage device 114, a communication bus 116, a communications unit 118, and one or more input/output (I/O) ports 119. The processor 112 performs computation functions associated with the methods and processes described herein including the prediction of the 3D microhardness distribution. The processor 112 can be any custom made or commercially available processor, a central processing unit (CPU), a graphics processing unit (GPU), an auxiliary processor among several processors, a semiconductor-based microprocessor (in the form of a microchip or chip set), a macroprocessor, any combination thereof, or generally any device for executing instructions.

The computer readable storage device 114 may include volatile and nonvolatile storage in read-only memory (ROM), random-access memory (RAM), and keep-alive memory (KAM), for example. KAM is a persistent or non-volatile memory that may be used to store various operating variables while the processor is powered down. The computer readable storage device 114 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the processor in performing the machine learning.

The communication bus 116 serves to transmit programs, data, status and other information or signals between the various components of the prediction computer system 110. The communication bus 116 can be any suitable physical or logical means of connecting computer systems and components. This includes, but is not limited to, direct hard-wired connections, fiber optics, infrared, and wireless bus technologies.

The communications unit 118 is configured to facilitate the transfer of programs, data, status and other information or signals between the various components of the prediction computer system 110 and other systems and devices, such as the user interface 120, the data storage device 130, the microhardness testing device 140, and the temperature sensor 150. The communications unit 118 may include various network components such as but not limited to one or more network transceivers for Ethernet connectivity to other network entities and an Internet connection. In various embodiments, the communications unit 118 may communicate with other systems or devices via the I/O port(s) 119. The I/O port(s) 119 may include various technologies such as universal serial bus (USB) technologies and the like.

The instructions may include one or more separate programs, each of which comprises an ordered listing of executable instructions for implementing logical functions. The instructions, when executed by the processor 112, receive and process signals, perform logic, calculations, methods and/or algorithms, and generate data based on the logic, calculations, methods, and/or algorithms. Although only one processor 112 is shown in FIG. 1, embodiments of the system can include any number of processors 112 that communicate over any suitable communication medium or a combination of communication mediums and that cooperate to process signals, perform logic, calculations, methods, and/or algorithms, and generate data.

The user interface 120 may be any system, device, or combination of devices that provide for interaction between the user and the microhardness prediction system 100, including user input and control of the microhardness prediction system 100 and information feedback from the microhardness prediction system 100 to the user. The user interface 120 may include various physical input hardware such as keyboards, pointing devices (e.g., mice, trackballs, etc.), and touchscreens, and output hardware such as computer monitors, speakers, and printers.

As can be appreciated, that the microhardness prediction system 100 may otherwise differ from the embodiment depicted in FIG. 1. For example, the microhardness prediction system 100 may be coupled to or may otherwise utilize one or more remote computer systems and/or other control systems, for example as part of one or more of the above-identified devices and systems. It will be appreciated that while this exemplary embodiment is described in the context of a fully functioning computer system, those skilled in the art will recognize that the mechanisms of the present disclosure are capable of being distributed as a program product with one or more types of non-transitory computer-readable signal bearing media used to store the program and the instructions thereof and carry out the distribution thereof, such as a non-transitory computer readable medium bearing the program and containing computer instructions stored therein for causing a computer processor (such as the processor 112) to perform and execute the program. Such a program product may take a variety of forms, and the present disclosure applies equally regardless of the particular type of computer-readable signal bearing media used to carry out the distribution. Examples of signal bearing media include recordable media such as floppy disks, hard drives, memory cards and optical disks, and transmission media such as digital and analog communication links. It will be appreciated that cloud-based storage and/or other techniques may also be utilized in certain embodiments. It will similarly be appreciated that the computer system of the microhardness prediction system 100 may also otherwise differ from the embodiment depicted in FIG. 1, for example in that the computer system of the microhardness prediction system 100 may be coupled to or may otherwise utilize one or more remote computer systems and/or other control systems.

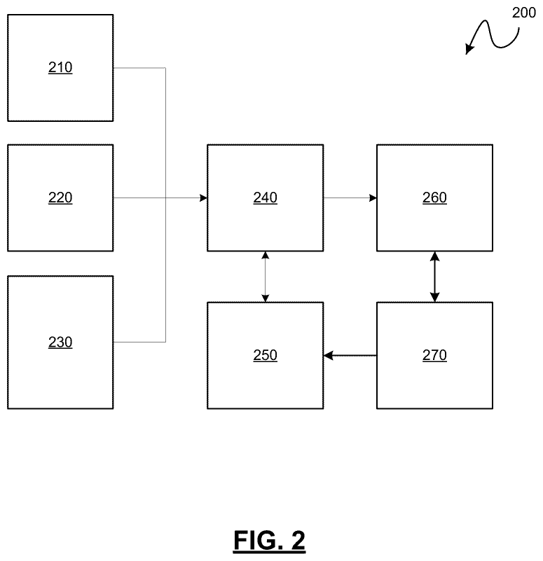

With reference to FIG. 2 and with continued reference to FIG. 1, a data flow diagram is illustrated of the microhardness prediction system 100 of FIG. 1 in accordance with various embodiments. As can be appreciated, various embodiments of the microhardness prediction system 100 according to the present disclosure may include any number of modules embedded within the components of the microhardness prediction system 100 which may be combined and/or further partitioned to similarly implement systems and methods described herein. Furthermore, inputs to the microhardness prediction system 100 may be received from other control modules (not shown), and/or determined/modeled by other sub-modules (not shown) within the microhardness prediction system 100. Furthermore, the inputs might also be subjected to preprocessing, such as sub-sampling, noise-reduction, normalization, feature-extraction, missing data reduction, and the like. In various embodiments, the microhardness prediction system 100 includes a temperature module 242, a correlation module 240, and an update module 250.

In various embodiments, the temperature module 242 receives as input temperature data 220. The temperature data 220 includes various data indicating temperature values that are each attributed to a corresponding one of a plurality of points of the weld at corresponding times during a welding process used to produce the weld. In various embodiments, the temperature data 220 may be generated and received from the temperature sensor 150. In other embodiments, the temperature data 220 may be received from a temperature simulation module of the microhardness prediction system 100 or another computer system.

The temperature module 242 performs an analysis of the temperature data 220 and determines peak temperature values and cooling rate values for each of the points of the weld based on the temperature profile. The temperature module 242 generates temperature distribution data 222 that includes the peak temperature values and cooling rate values.

In various embodiments, the correlation module 240 receives as input the temperature distribution data 222 generated by the temperature module 242. The correlation module 240 may also receive two-dimensional (2D) microhardness map data 210 that includes various data indicating a two-dimensional (2D) distribution of microhardness values each attributed to a corresponding one of the plurality of points of the weld. The correlation module 240 may also receive additional data 230 that includes various data indicating, for example, compositions of the workpieces, microhardness values associated with the workpieces prior to the welding process, thermal histories of the workpieces, etc. In various embodiments, the 2D microhardness map data 210 may be received from the microhardness testing device 140. In various embodiments, the additional data 230 may be received from the data storage device 130.

In various embodiments, the correlation module 240 uses the temperature distribution data 222, the 2D microhardness map data 210, and/or the additional data 230 to train a machine learning module 290 thereof. The training may include correlating, by a machine learning method, the 2D distribution of microhardness values with the peak temperature values and the cooling rate values of the weld to provide correlation results. Optionally, the training may further include correlating the 2D distribution of microhardness values with the compositions, the microhardness values, and/or other information of the additional data 230 to provide the correlation results. In various embodiments, the machine learning module 290 may include a neural network.

In various embodiments, the correlation module 240 uses the temperature distribution data 222, the 2D microhardness map data 210, and/or the additional data 230 to execute the machine learning module 290 thereof wherein the correlation results are used to predict the 3D distribution of microhardness values of the weld. The correlation module 240 generates three-dimensional (3D) microhardness distribution data 260 that includes the predicted 3D distribution of microhardness values of the weld. In some embodiments, the microhardness prediction system 100 may include a display module configured to receive the predicted 3D distribution of microhardness values from the correlation module 240, generate display data therefrom, and transmit the display data to be received and rendered as visual information on the user interface 120 or other display system.

In various embodiments, the update module 250 receives as input verification data 270. The verification data 270 includes various data indicating microhardness values attributed at least some of the plurality of points of the weld as determined by with verification testing (e.g., physical experiment results). In various embodiments, the verification testing may be performed, at least in part, with the 2D microhardness testing device 140.

The update module 250 performs an analysis of the verification data 270 to determine the accuracy of the predicted 3D distribution of microhardness values of the weld included in the 3D microhardness distribution data 260. The update module 250 may generate update data 280 that includes information related to the analysis. In various embodiments, the update data 280 may be received by the correlation module 240 and used for updating the machine learning module 290 to promote accuracy of the 3D microhardness distribution data 260.

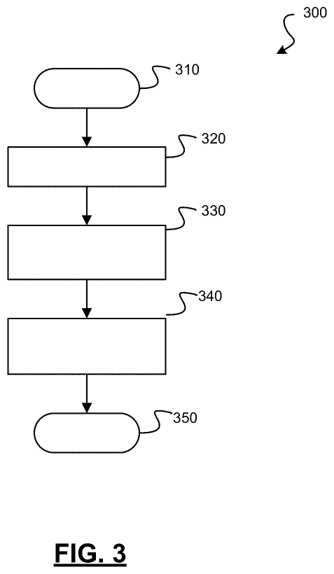

With reference now to FIG. 3 and with continued reference to FIGS. 1-2, a flowchart provides a computer implemented training method 300 for training the machine learning module 290 of the correlation module 240. In various embodiments, the machine learning module 290 may include a neural network. The training may be performed to promote accurate generation of predictions of three-dimensional (3D) microhardness distributions of a weld that defines a weld joint between workpieces as performed by the microhardness prediction system 100, in accordance with exemplary embodiments. As can be appreciated in light of the disclosure, the order of operation within the training method 300 is not limited to the sequential execution as illustrated in FIG. 3, but may be performed in one or more varying orders as applicable and in accordance with the present disclosure.

In one example, the training method 300 may begin at 310. At 320, the method includes obtaining or receiving, by the processor 112, training data for use in training the machine learning module 290 of the correlation module 240. The training data includes the 2D microhardness map data 210 that includes one or more two-dimensional (2D) distributions of microhardness values of one or more weld(s) each including a plurality of points corresponding to microhardness values obtained at various corresponding points on one or more cross-sectional specimens of the weld(s). In some embodiments, the microhardness values may include a line distribution. The 2D microhardness map data 210 may be input by a user via the user interface 120, received from the microhardness testing device 140, or received from another device or source.

The training data further includes the temperature data 220 associated with the welding process used to produce the weld. The temperature data 220 includes temperature values for each of the plurality of points within the 2D microhardness map data 210, that is, for the same corresponding various points on the weld. The temperature data 220 may be input by the user via the user interface 120, received from the temperature sensor 150, or received from another device or source. The temperature values may be evaluated to determine peak temperature values and cooling rate values for the points, or such information may be included in the temperature data 220.

At 330, the method 300 includes determining correlations between the 2D microhardness map data 210 (e.g., microhardness values associated with the points of the weld) and the temperature data 220 and/or information derived therefrom (e.g., the peak temperature values and the cooling rate values) to train the machine learning module 290. At 340, the method 300 includes training (e.g., by the processor 112), the machine learning module 290, including learning to predict a correlation result. The correlation result includes and/or is used to generate the 3D microhardness distribution data 260 based on the peak temperature values and the cooling rate values of a weld. The training method 300 may end at 350.

In various embodiments, the training data further includes the additional data 230 which may include, for example, composition data that includes compositions of the workpieces, and material microhardness data that includes microhardness measurement values of the base metals of the workpieces. In these embodiments, the method 300 includes correlating the 2D microhardness map data 210 with the temperature data 220, and the additional data 230 (e.g., the composition data and the material microhardness data) and training the machine learning module 290 to generate the 3D microhardness distribution data 260 based on the 2D microhardness map, the peak temperature, the cooling rate, the compositions of the workpieces, and the microhardness measurement values of the base metals of the workpieces. The additional data 230 may be beneficial as input when predicting 3D microhardness distributions for workpieces formed of dissimilar (i.e., different) materials. Other nonlimiting examples of information that may be in the additional data 230 and used by the prediction computer system 110 to train the machine learning module 290 may include initial microhardness measurement values of the workpieces obtained prior to welding and temperature histories of the workpieces.

In various embodiments, the method 300 further includes obtaining, producing, or generating the 2D microhardness map data 210 via physical testing, such as with the microhardness testing device 140. In these embodiments, the method 300 may include producing one or more specimens that each include a cross-section of the weld, performing microhardness testing on a plurality of points on the specimen(s) to obtain the microhardness values for each of the plurality of points, generating the 2D distribution of microhardness values of the weld based on the microhardness values for each of the plurality of points, and generating the 2D microhardness map data 210 comprising the 2D distribution.

In various embodiments, the method 300 further includes obtaining, measuring, sensing, or generating the temperature data 220 via physical testing, such as with the temperature sensor 150. In these embodiments, the method 300 may include measuring or sensing temperatures of various points on the weld during the welding process to obtain the temperature values, generating the temperature distribution of the weld based on the temperature values, and generating the temperature data 220 comprising the temperature distribution. The temperature values may be obtained, measured, sensed, or generated during the welding process wherein the weld is being actively or passively reduced in temperature resulting in solidification thereof. In various embodiments, the cooling rates may be obtained, measured, sensed, or generated during a limited temperature range during the welding process. As nonlimiting examples, the cooling rates may be obtained, measured, sensed, or generated for workpieces formed of mild steels in a temperatures range of between about 800° C. and 500° C. and for workpieces formed of advanced high strength steels at temperatures between about 750° C. and 300° C.

Alternatively, the temperature values may be obtained, measured, sensed, or generated during the welding process, and the peak temperature values and the cooling rate values determined therefrom may be limited to within a limited temperature range that is narrower than the entire temperature range of the temperature values. For example, for workpieces formed of a mild steel, the processor 112 may determine the cooling rates in a temperature range of between about 800° C. and 500° C., and for workpieces formed of an advanced high strength steel, the processor 112 may determine the cooling rates in a temperature range of between about 750° C. and 300° C.

In various embodiments, the method 300 further includes obtaining or generating the temperature data 220 via simulations rather than physical testing. In these embodiments, the method 300 may include simulating temperatures of various points on the weld during the welding process using a computer implemented welding process simulation model to obtain simulated temperature measurement values, generating the temperature distribution of the weld based on the simulated temperature values, and generating the temperature data 220 comprising the temperature distribution.

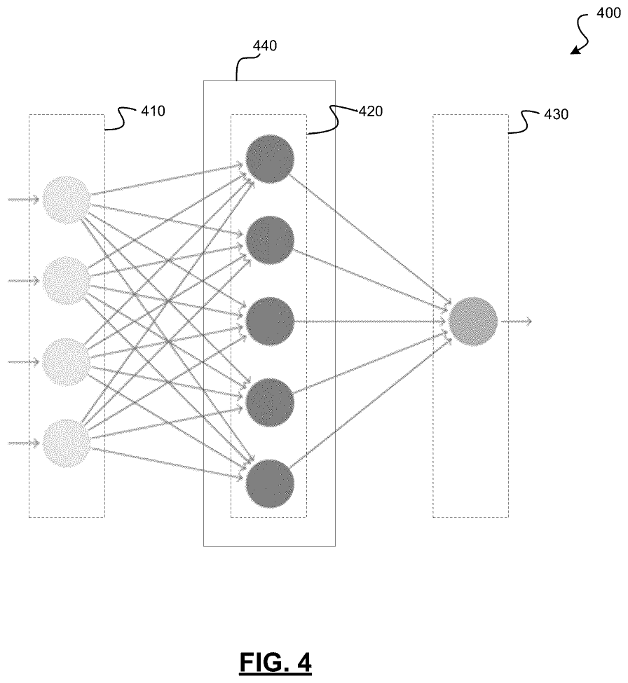

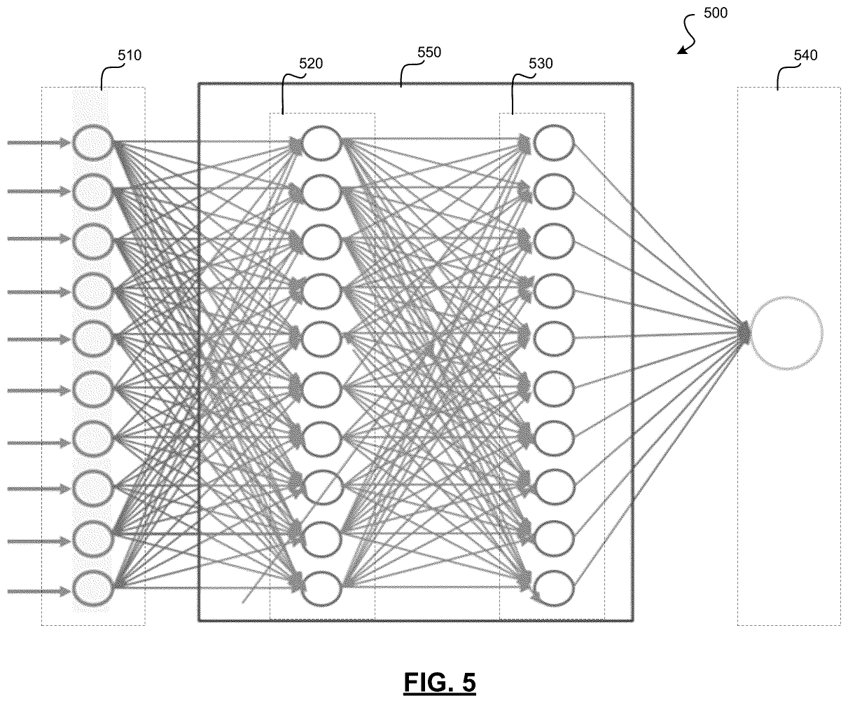

FIGS. 4 and 5 present nonlimiting examples of neural networks 400,500 that may be included in the machine learning module 290. As illustrated in FIG. 4, the neural network 400 includes a plurality of inputs 410 that are input from one side of the neural network 400 and a result 430 is output from the other side. The inputs 410 are weighted by corresponding weights and input into neurons 420 of a hidden layer 440 which output the result 430. The hidden layer 440 can contain multiple neurons defined by linear or nonlinear functions. For microhardness predictions, nonlinear functions such as sigmoid neurons may be used. The operation of the neural network 400 includes a learning process and an execution process. For example, the weights are learned using the training data (e.g., the 2D microhardness map data 210, the temperature data 220, and the additional data 230) in the learning process, and the correlation results in the microhardness prediction system 100 are generated using the trained machine learning module 290 in the execution process.

Additional numbers of layers may be added as needed (i.e., deep learning). For example, FIG. 5 illustrates the neural network 500 as including two hidden layers 550. In this example, a plurality of inputs 510 are weighted by corresponding weights and input into neurons 520 which in turn produce outputs weighted by corresponding weights and input into neurons 530 which output the result 540. The hidden layers 550 may function to enable the neural network 500 to reproduce nonlinear relationships between the inputs 510 (e.g., temperature distribution) and the result 540 (e.g., 3D hardness map). Each of the hidden layers 550 can contain multiple weighted neurons defined by linear or nonlinear functions, such as but not limited to sigmoid neurons. The hidden layers 550 may be specialized to better represent different functional characteristics of the problem to be solved. For example, one of the hidden layers 550 may be specifically trained to detect specific material phase transformations during the welding process. In various embodiments, the neural network 400 may be used for predictions when the workpieces are formed of similar materials, and the neural network 500 may be used for predictions when the workpieces are formed of dissimilar (i.e., different) materials.

It should be noted that the machine learning method may be different than as described herein and may use various machine learning techniques. Suitable techniques may include, but are not limited to, supervised learning (e.g., labeled input/desired output training data), unsupervised learning (e.g., unlabeled training data), semi-supervised learning (e.g., small amount of labeled training data), and reinforcement learning techniques (e.g., goal/rule algorithms).

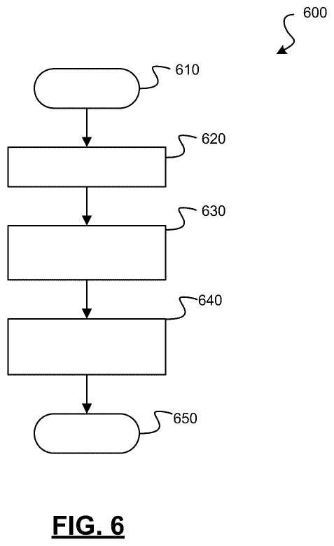

With reference now to FIG. 6 and with continued reference to FIGS. 1-5, a flowchart provides a computer implemented execution method 600 for executing the machine learning module 290 of the prediction computer system 110 for predicting a three-dimensional (3D) microhardness distribution of a weld that defines a weld joint between workpieces as performed by the microhardness prediction system 100, in accordance with exemplary embodiments. As can be appreciated in light of the disclosure, the order of operation within the execution method 600 is not limited to the sequential execution as illustrated in FIG. 6, but may be performed in one or more varying orders as applicable and in accordance with the present disclosure.

In one example, the execution method 600 may begin at 610. At 620, the method 600 includes receiving or obtaining the temperature data 220, by the processor 112, that includes a temperature distribution associated with the welding process used to produce the weld. The temperature data 220 may include peak temperature values and cooling rate values at a plurality of points of the weld during the welding process, or temperature values from which the peak temperature values and the cooling rate values may be determined. At 630, the temperature data 220 is processed, by the machine learning module 290 (e.g., neural network 400,500) to generate a prediction of the 3D microhardness distribution of the weld. At 640, the prediction is provided of the 3D microhardness distribution to the user interface 120 as the 3D microhardness distribution data 260. The method 600 may end at 650.

In various embodiments, the method 600 may further include providing the 3D microhardness distribution data 260 to a computer-aided engineering (CAE) tool as input data, and performing an analysis with the CAE tool using the 3D microhardness distribution as input. Nonlimiting examples of analyses performed using the CAE tool may include predicting a load carrying capacity or a strength of a weld, or predicting how much energy is dissipated when a weld is loaded to failure. More generally, the 3D microhardness distribution may be used to inform the material properties governing plastic deformation within the CAE tool. As a specific nonlimiting example, the 3D microhardness distribution may be used as input within the CAE tool to model mechanical performance of multiple welded components and/or structures of a vehicle to simulate the crashworthiness of the vehicle.

In various embodiments, the at least two workpieces are formed of an advanced high strength steel with certain volume fraction of martensite in the base metal, the heat affected zone of the weld may include a tempered zone. In these embodiments, the prediction of the 3D microhardness distribution includes the tempered zone, and the prediction of the 3D microhardness distribution is generated by the machine learning module 290 (e.g., neural network 400, 500) without generating tempering kinematics experimentally for the tempered zone.

As used herein a “metal” workpiece or a workpiece comprised of the “metal or metal alloy”, refers to such workpieces that are at least 10 wt. % of the named metal. In certain embodiments, such workpieces are at least 25 wt. %, such as at least 50 wt. %, for example at least 75 wt. %, such as at least 80 wt. %, for example at least 95 wt. % of the named metal. Elements of a metal alloy other than the named metal are referred to herein as alloying elements. As used herein, a “base metal” refers to the predominate element of a metal or metal alloy, also referred to above as the named metal.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A system for predicting microhardness properties of a weld that defines a weld joint between at least two workpieces, the system comprising:
a processor programmed to:
receive temperature data that includes sensed or simulated temperature values each attributed to a corresponding one of a plurality of points of the weld at corresponding times during a welding process used to produce the weld;
determine peak temperature values and cooling rate values for each of the points of the weld based on the temperature values;
predict a three-dimensional (3D) distribution of microhardness values of the weld based on a machine learning method that evaluates the peak temperature values and the cooling rate values; and
generate display data based on the 3D distribution of microhardness values.

2. The system of claim 1, wherein the processor is further programmed to:
receive composition data that includes compositions of the at least two workpieces;
receive material microhardness data that includes microhardness values of base metals of the at least two workpieces; and
predict the 3D distribution of microhardness values of the weld based on the machine learning method that evaluates the peak temperature values, the cooling rate values, the compositions of the at least two workpieces, and the microhardness values of the base metals.

3. The system of claim 1, wherein the processor is further programmed to:
simulate the temperature values using a welding process simulation model; and
generate the temperature data comprising the simulated temperature values.

4. The system of claim 1, further comprising:
a temperature sensor configured to:
sense the temperature values of the welding process; and
transmit the sensed temperature values to the processor as the temperature data;
wherein the at least two workpieces are formed of a mild steel;
wherein the processor determines the cooling rate values in a temperature range of between about 800° C. and 500° C.

5. The system of claim 1, further comprising:
a temperature sensor configured to:
sense the temperature values during the welding process; and
transmit the sensed temperature values to the processor as the temperature data;
wherein the at least two workpieces are formed of an advanced high strength steel;
wherein the processor determines the cooling rate values in a temperature range of between about 750° C. and 300° C.

6. The system of claim 1, wherein the processor is further programmed to:
provide the 3D distribution of microhardness values to a computer-aided engineering (CAE) tool as input data; and
perform an analysis with the CAE tool using the 3D distribution of microhardness values as input.

7. The system of claim 1, wherein the at least two workpieces are formed of an advanced high strength steel that includes a volume fraction of martensite, wherein a heat affected zone of the weld includes a tempered zone, at least some of the microhardness values of the 3D distribution are attributed to points within the tempered zone, and the processor is programmed to predict the 3D distribution of microhardness values without using martensite tempering kinetics produced experimentally for the tempered zone.

8. The system of claim 1, wherein the processor is further programmed to:
receive two-dimensional (2D) distribution data that comprises a two-dimensional (2D) distribution of microhardness values each attributed to a corresponding one of the plurality of points of the weld;
correlate, by the machine learning method, the 2D distribution of microhardness values with the peak temperature values and the cooling rate values of the weld to provide correlation results; and
train a neural network with the correlation results to predict the 3D distribution of microhardness values of the weld.

9. The system of claim 1, wherein the processor is further programmed to:
receive two-dimensional (2D) distribution data that comprises a two-dimensional (2D) distribution of microhardness values each attributed to a corresponding one of the plurality of points of the weld after solidification of the weld;
receive composition data that includes compositions the at least two workpieces;
receive material microhardness data that includes microhardness values of base metals of the at least two workpieces;
correlate, by the machine learning method, the 2D distribution of microhardness values with the peak temperature values, the cooling rate values, the compositions, and the microhardness values to provide correlation results; and
train a neural network with the correlation results to predict the 3D distribution of microhardness values of the weld.

10. The system of claim 9, further comprising:
a microhardness testing device configured to:
measure the 2D distribution of microhardness values of the weld; and
transmit the 2D distribution of microhardness values to the processor as the 2D distribution data.

11. A computer implemented method for predicting microhardness properties of a weld that defines a weld joint between at least two workpieces, the method comprising:
receiving, by a processor, temperature data that includes sensed or simulated temperature values each attributed to a corresponding one of a plurality of points of the weld at corresponding times during a welding process used to produce the weld;
determining, by the processor, peak temperature values and cooling rate values for each of the points of the weld based on the temperature values;
predicting, by the processor, a three-dimensional (3D) distribution of microhardness values of the weld based on a machine learning method that evaluates the peak temperature values and the cooling rate values; and
generating, by the processor, display data based on the 3D distribution of microhardness values.

12. The method of claim 11, further comprising, by the processor:
receiving composition data that includes compositions of the at least two workpieces;
receiving material microhardness data that includes microhardness values of base metals of the at least two workpieces; and
predicting the 3D distribution of microhardness values of the weld based on the machine learning method that evaluates the peak temperature values, the cooling rate values, the compositions of the at least two workpieces, and the microhardness values of the base metals.

13. The method of claim 11, further comprising, by the processor:
simulating the temperature values using a welding process simulation model; and
generating the temperature data comprising the simulated temperature values.

14. The method of claim 11, further comprising:
sensing, with a temperature sensor, the temperature values during a welding process; and
transmitting the sensed temperature values to the processor as the temperature data;
wherein the at least two workpieces are formed of a mild steel;
wherein the processor determines the cooling rate values in a temperature range of between about 800° C. and 500° C.

15. The method of claim 11, further comprising:
sensing, with a temperature sensor, the temperature values during the welding process; and
transmitting the sensed temperature values to the processor as the temperature data;
wherein the at least two workpieces are formed of an advanced high strength steel;
wherein the processor determines the cooling rate values in a temperature range of between about 750° C. and 300° C.

16. The method of claim 11, further comprising, by the processor:
providing the 3D distribution of microhardness values to a computer-aided engineering (CAE) tool as input data; and
performing an analysis with the CAE tool using the 3D distribution of microhardness values as input.

17. The method of claim 11, wherein the at least two workpieces are formed of an advanced high strength steel that includes a volume fraction of martensite, wherein a heat affected zone of the weld includes a tempered zone, at least some of the microhardness values of the 3D distribution are attributed to points within the tempered zone, and the method further comprises, by the processor, predicting the 3D distribution of microhardness values without using tempering kinetics produced experimentally for the tempered zone.

18. The method of claim 11, further comprising, by the processor:
receiving two-dimensional (2D) distribution data that comprises a two-dimensional (2D) distribution of microhardness values each attributed to a corresponding one of the plurality of points of the weld after solidification of the weld;
correlating, by the machine learning method, the 2D distribution of microhardness values with the peak temperature values and the cooling rate values of the weld to provide correlation results; and
training a neural network with the correlation results to predict the 3D distribution of microhardness values of the weld.

19. The method of claim 11, further comprising, by the processor:
receiving two-dimensional (2D) distribution data that comprises a two-dimensional (2D) distribution of microhardness values each attributed to a corresponding one of the plurality of points of the weld after solidification of the weld;
receiving composition data that includes compositions the at least two workpieces;
receiving material microhardness data that includes microhardness values of base metals of the at least two workpieces; and
correlating, by the machine learning method, the 2D distribution of microhardness values with the peak temperature values, the cooling rate values, the compositions, and the microhardness values to provide correlation results; and
training a neural network with the correlation results to predict the 3D distribution of microhardness values of the weld.

20. The method of claim 18, further comprising, by a microhardness testing device:
measuring the 2D distribution of microhardness values of the weld; and
transmitting the 2D distribution of microhardness values to the processor as the 2D distribution data.
